(19) United States
(12) Patent Application Publication
(10) Pub. No.: US 2019/0088570 A1
(43) Pub. Date: Mar. 21, 2019

(54) SEMICONDUCTOR DEVICE, SOLID-STATE IMAGING DEVICE, AND ELECTRONIC APPARATUS

(71) Applicant: SONY CORPORATION, TOKYO (JP)

(72) Inventors: YUSUKE MADA, TOKYO (JP); KAZUHIRO HONGO, KANAGAWA (JP)

(21) Appl. No.: 16/085,679

(22) PCT Filed: Mar. 10, 2017
(86) PCT No.: PCT/JP2017/009668

§ 371 Date: Sep. 17, 2018

(30) Foreign Application Priority Data
Mar. 24, 2016 (JP) 2016-060342

(51) Int. Cl. H01L 23/373; H05K 1/18; H01L 23/00; H01L 27/146; H05K 1/02

(52) U.S. Cl. CPC H01L 23/373; H05K 1/181; H01L 23/562; H04N 5/335; H05K 1/0271; H05K 2201/10151; H05K 2201/10121; H01L 27/14643

(57) ABSTRACT

The present disclosure relates to a semiconductor device, a solid-state imaging device, and an electronic apparatus that can reduce warping. In a mounted substrate, the solid-state imaging device has a light receiving surface on which a subject image is incident, and by connecting solder balls disposed on the back surface of the light receiving surface to a wiring substrate, it is possible to take out an electric signal to the outside for image recognition. Furthermore, a thermal expansion adjustment member is provided on the side opposite to the solid-state imaging device mounted on the wiring substrate. The linear expansion coefficient and the Young's modulus of the thermal expansion adjustment member are adjusted, so that rigidity is equal or substantially equal between the solid-state imaging device side and the thermal expansion adjustment member side. The present disclosure can be applied, for example, to a CMOS solid-state imaging device used for an imaging device such as a camera.

### TECHNICAL FIELD

The present disclosure relates to a semiconductor device, a solid-state imaging device, and an electronic apparatus, and in particular, relates to a semiconductor device, a solid-state imaging device, and an electronic apparatus in which warping can be reduced.

### BACKGROUND ART

In recent years, size reduction, weight reduction, and functionality improvement of a smartphone and other electronic products are rapidly realized. Along with these market trends, size reduction, weight reduction, and thickness reduction are strongly required also for semiconductor package components mounted on electronics products. In particular, the height of a camera module mounted on a smartphone determines the thickness of the smartphone, and therefore it is essential to reduce the height of the camera module. Therefore, in order to reduce the height of the camera module, thickness reduction of components inside the camera module is also being realized. As thickness reduction reduces rigidity of each component, problems such as warping are more likely to occur.

An example of the camera module is a mounted substrate in which an imaging element has a light receiving surface on which a subject image is incident, and by connecting solder balls disposed on the back surface of the light receiving surface to a wiring substrate, it is possible to take out an electric signal to the outside for image recognition.

In such a mounted state, due to a difference in thermal expansion coefficient between the imaging element and the wiring substrate, warping may be caused by a change in environmental temperature, or heat generation by the imaging element during actual use. In particular, in a case where rigidity of the component is lowered, the warping becomes conspicuous.

Therefore, as a structure for lessening warping, a wiring substrate structure having a thermal expansion adjustment member inside is proposed (see Patent Document 1). With this structure, it is possible to make thermal expansion coefficients of an imaging element side and a thermal expansion adjustment member side symmetrical with respect to the wiring substrate serving as a boundary, and it is possible to cancel out warping caused by the difference in thermal expansion coefficient.

### CITATION LIST

### Patent Document

Patent Document 1: Japanese Patent Application Laid-Open No. 2011-40428

### SUMMARY OF THE INVENTION

### Problems to be Solved by the Invention

However, with this structure, it is necessary to prepare a thermal expansion adjustment member corresponding to the size and the thermal expansion coefficient of the imaging element, in advance, to manufacture a wiring substrate, which makes it difficult to make a modification afterward. In particular, in such a case of using a super-resolution technique, warping in a surface of the imaging element will exert a conspicuous influence which is deterioration in image quality.

In addition, by embedding the thermal expansion adjustment member in the wiring substrate, wiring resources in the substrate are extremely reduced, and wiring design becomes difficult.

The present disclosure is made in view of such a situation, and can reduce warping.

### Solution to Problems

A semiconductor device according to an aspect of the present technology has a structure including a substrate on which a semiconductor element is mounted and a thermal expansion adjustment member which is provided on a surface of the substrate, the surface being opposite to a surface on which the semiconductor element is mounted, in which a substance value and a shape of the thermal expansion adjustment member are adjusted such that a linear expansion coefficient and a Young's modulus are adjusted so as to be substantially equal between a solid-state imaging device side of a neutral plane with respect to entire rigidity of the structure and a thermal expansion adjustment member side of the neutral plane.

The substance value and the shape of the thermal expansion adjustment member are adjusted so as to substantially satisfy the following expressions.

$$\begin{matrix}[ Expression 1 ] & \\ ( 1 + {α}_{2} Δ T ) ( 1 - {Δɛ}_{2} ) = ( 1 + {α}_{3} Δ T ) ( 1 - {Δɛ}_{3} ) & \\ [ Expression 2 ] & \\ {Δɛ}_{2} = \frac{( {α}_{1} - {α}_{2} ) Δ T}{( 1 + {α}_{2} Δ T ) + \frac{1 - {v}_{1} {E}_{2} {t}_{2}}{1 - {v}_{2} {E}_{1} {t}_{1}} ( 1 + {α}_{1} Δ T )} & \\ [ Expression 3 ] & \\ {Δɛ}_{3} = \frac{( {α}_{4} - {α}_{3} ) Δ T}{( 1 + {α}_{3} Δ T ) + \frac{1 - {v}_{4} {E}_{3} {t}_{3}}{1 - {v}_{3} {E}_{4} {t}_{4}} ( 1 + {α}_{4} Δ T )} & \end{matrix}$$

Here, Δ_{ϵ} may represent strain of a member, E may represent a Young's modulus, ν may represent a Poisson's ratio, α may represent a linear expansion coefficient, t may represent a thickness, and ΔT may represent a temperature change.

The substance value and the shape of the thermal expansion adjustment member are adjusted so as to substantially satisfy the expressions.

Accuracy of each of the substance value and the shape of the thermal expansion adjustment member is adjusted so as to satisfy a variation of ±5% or less.

The thermal expansion adjustment member may have a shape substantially equal to the shape of the semiconductor element.

An opening may be provided in part of the thermal expansion adjustment member.

The thermal expansion adjustment member is divided into a plurality of parts.

The thermal expansion adjustment member is an active element having a function of supporting the semiconductor element.

The semiconductor element is a solid-state imaging element or an inertial sensor.

A solid-state imaging device according to an aspect of the present technology has a structure including a substrate on which a solid-state imaging element is mounted and a thermal expansion adjustment member which is provided on a surface of the substrate, the surface being opposite to a surface on which the solid-state imaging element is mounted, in which a substance value and a shape of the thermal expansion adjustment member are adjusted such that a linear expansion coefficient and a Young's modulus are adjusted so as to be equal between a solid-state imaging device side of a neutral plane with respect to entire rigidity of the structure and a thermal expansion adjustment member side of the neutral plane.

An electronic apparatus according to an aspect of the present technology has a structure including a substrate on which a solid-state imaging element is mounted, and a thermal expansion adjustment member which is provided on a surface of the substrate, the surface being opposite to a surface on which the solid-state imaging element is mounted, in which a substance value and a shape of the thermal expansion adjustment member are adjusted such that a linear expansion coefficient and a Young's modulus are adjusted so as to be substantially equal between a solid-state imaging device side of a neutral plane with respect to entire rigidity of the structure and a thermal expansion adjustment member side of the neutral plane.

According to an aspect of the present technology, a structure includes a substrate on which a solid-state imaging element is mounted and a thermal expansion adjustment member which is provided on a surface of the substrate, the surface being opposite to a surface on which the solid-state imaging element is mounted. Then, a substance value and a shape of the thermal expansion adjustment member are adjusted such that a linear expansion coefficient and a Young's modulus are adjusted so as to be substantially equal between a solid-state imaging device side of a neutral plane with respect to entire rigidity of the structure and a thermal expansion adjustment member side of the neutral plane.

### Effects of the Invention

According to present technology, warping can be reduced.

Note that the effects described herein are only illustrative and the effects of present technology are not limited to the effects described herein but may have additional effects.

### BRIEF DESCRIPTION OF DRAWINGS

FIG. 1 is a block diagram illustrating a schematic configuration example of a solid-state imaging device to which the present technology is applied.

FIG. 2 is a view illustrating a structural example of a mounted substrate.

FIG. 3 is a view illustrating another structural example of the mounted substrate.

FIG. 4 is a view illustrating a structural example of the mounted substrate to which the present technology is applied.

FIG. 5 is a diagram schematically illustrating the structural example of FIG. 4.

FIG. 6 is a view illustrating another structural example of the mounted substrate to which the present technology is applied.

FIG. 7 is a view illustrating a yet another structural example of the mounted substrate to which the present technology is applied.

FIG. 8 is a view illustrating another structural example of the mounted substrate to which the present technology is applied.

FIG. 9 is a diagram illustrating usage examples of an image sensor to which the present technology is applied.

FIG. 10 is a block diagram illustrating a configuration example of an electronic apparatus to which the present technology is applied.

### MODE FOR CARRYING OUT THE INVENTION

Hereinafter, modes for implementing the present disclosure (hereinafter referred to as embodiments) will be described. Note that the description of the embodiments will be given in the following order.

1. First Embodiment

2. Second Embodiment (Usage Examples of Image Sensor)

3. Third Embodiment (Example of Electronic Apparatus)

### 1. First Embodiment

<Schematic Configuration Example of Solid-State Imaging Device>

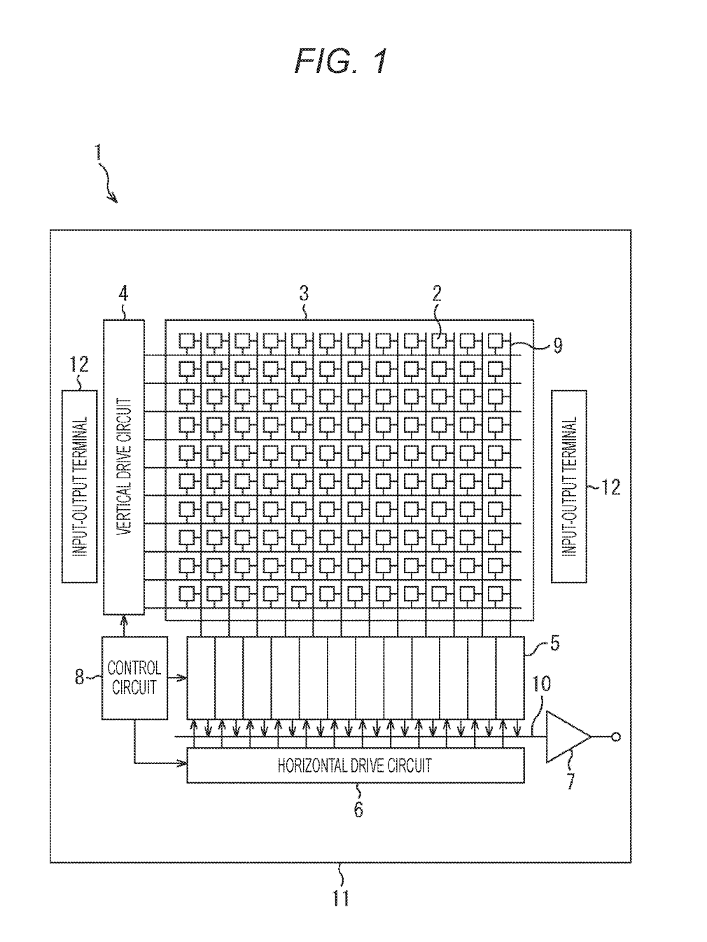

FIG. 1 illustrates one schematic configuration example of a Complementary Metal Oxide Semiconductor (CMOS) solid-state imaging device applied to each embodiment of the present technology.

As illustrated in FIG. 1, a solid-state imaging device (element chip) 1 has a structure in which, on a semiconductor substrate 11 (for example, a silicon substrate), a pixel area (so-called imaging area) 3 where a plurality of pixels 2 including photoelectric conversion elements is regularly arranged two-dimensionally and a peripheral circuit area are provided.

The pixel 2 includes the photoelectric conversion element (for example, a Photo Diode (PD)) and a plurality of pixel transistors (so-called MOS transistors). The plurality of pixel transistors may include, for example, three transistors, that is, a transfer transistor, a reset transistor, and an amplification transistor, or may include four transistors by further adding a selection transistor.

Furthermore, the pixels 2 may also have a pixel sharing structure. The pixel sharing structure includes a plurality of photodiodes, a plurality of transfer transistors, one shared floating diffusion, and one of each of the other pixel transistors that is shared. The photodiode is a photoelectric conversion element.

The peripheral circuit area includes a vertical drive circuit 4, a column signal processing circuit 5, a horizontal drive circuit 6, an output circuit 7, and a control circuit 8.

The control circuit 8 receives data instructing an input clock, an operation mode, and the like, and furthermore, outputs data such as internal information of the solid-state imaging device 1. Specifically, on the basis of a vertical synchronizing signal, a horizontal synchronizing signal, and a master clock, the control circuit 8 generates a clock signal and a control signal which serve as references for operation of the vertical drive circuit 4, the column signal processing circuit 5, and the horizontal drive circuit 6. Then, the control circuit 8 inputs these signals to the vertical drive circuit 4, the column signal processing circuit 5, and the horizontal drive circuit 6.

The vertical drive circuit 4 includes for example, a shift register, selects pixel drive wiring, supplies a pulse for driving the pixel 2 to the selected pixel drive wiring, and drives the pixels 2 in units of rows. Specifically, the vertical drive circuit 4 sequentially selects and scans each pixel 2 of the pixel area 3 in the vertical direction in units of rows, and supplies a pixel signal based on signal charges generated according to the light reception amount in the photoelectric conversion element of each pixel 2 through a vertical signal line 9 to the column signal processing circuit 5.

The column signal processing circuit 5 is disposed for example, for each column of the pixels 2, and subjects a signal output from the pixel 2 in one row to a signal process such as noise reduction for each pixel column. Specifically, the column signal processing circuit 5 performs signal processes such as Correlated Double Sampling (CDS) for removing fixed pattern noise unique to the pixel 2, signal amplification, and Analog/Digital (A/D) conversion. A horizontal selection switch (not illustrated) is connected to an output stage of the column signal processing circuit 5 so as to be provided between the output stage and a horizontal signal line 10.

The horizontal drive circuit 6 includes, for example, a shift register, and sequentially outputs horizontal scanning pulses to select each of the column signal processing circuits 5 in order and to cause each of the column signal processing circuits 5 to output a pixel signal to the horizontal signal line 10.

The output circuit 7 performs a signal process on the signals sequentially supplied from the respective column signal processing circuits 5 through the horizontal signal line 10, and outputs the signals. The output circuit 7 may perform, for example, only buffering, or may perform black level adjustment, column variation correction, various digital signal processes, and the like.

An input-output terminal 12 is provided for exchanging signals with the outside.

<Structural Example of Mounted Substrate>

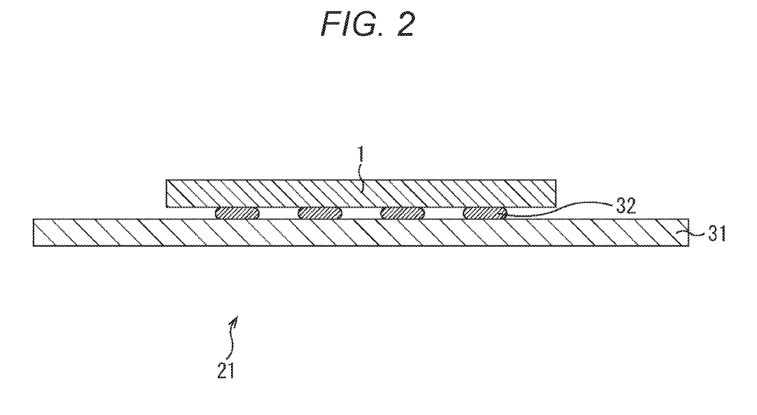

FIG. 2 is a view illustrating a structural example of a mounted substrate. In a mounted substrate 21 of FIG. 2, the solid-state imaging device 1 has a light receiving surface on which a subject image is incident, and by connecting solder balls 32 disposed on the back surface of the light receiving surface to a wiring substrate 31, an electric signal can be taken out to the outside for image recognition.

However, in such a mounted state, due to a difference in thermal expansion coefficient between the solid-state imaging device 1 and the wiring substrate 31, warping may be caused by a change in environmental temperature, or heat generation by the solid-state imaging device 1 during actual use. In particular, in a case where rigidity of the component is lowered, the warping becomes conspicuous.

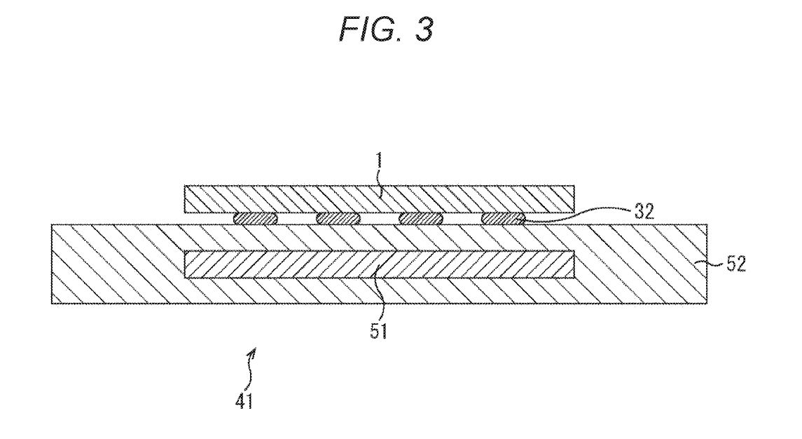

Therefore, as a method for lessening warping, the structure illustrated in FIG. 3 is proposed.

FIG. 3 is a view illustrating another structural example of the mounted substrate. In a mounted substrate 41 of FIG. 3, a thermal expansion adjustment member 51 is buried in a wiring substrate 52 to which a solid-state imaging device 1 is connected with solder balls 32. With this arrangement, it is possible to make thermal expansion coefficients of a solid-state imaging device 1 side and a thermal expansion adjustment member 51 side symmetrical with respect to the wiring substrate 52 serving as a boundary, and it is possible to cancel out warping caused by the difference in thermal expansion coefficient.

Note that the structure of the mounted substrate 41 of FIG. 3 is created by embedding the thermal expansion adjustment member 51 to perform insert molding when the substrate is formed.

However, with this structure, it is necessary to prepare the thermal expansion adjustment member 51 corresponding to the size and the thermal expansion coefficient of the solid-state imaging device 1 in advance to manufacture the wiring substrate 52, which makes it difficult to make a modification afterward. In particular, in such a case of using a super-resolution technique, warping in a surface of the solid-state imaging device 1 will exert a conspicuous influence which is deterioration in image quality.

In addition, by embedding the thermal expansion adjustment member 51 in the wiring substrate 52, wiring resources in the wiring substrate 52 are extremely reduced, and wiring design becomes difficult.

<Structural Example of Mounted Substrate of Present Technology>

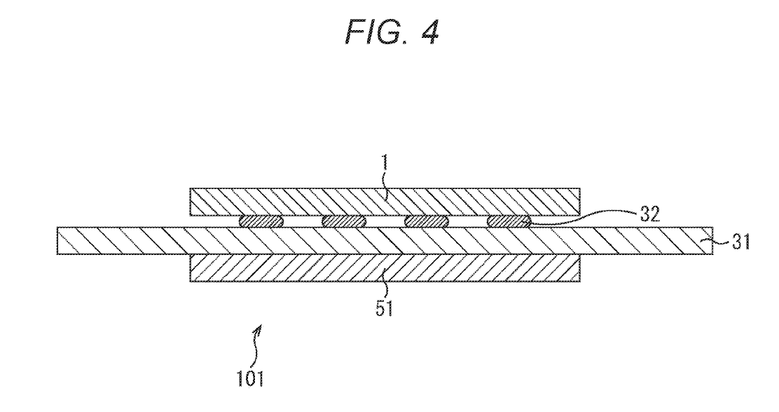

FIG. 4 is a diagram illustrating a structural example of a mounted substrate to which the present technology is applied.

In a mounted substrate 101 of FIG. 4, a solid-state imaging device 1 has a light receiving surface on which a subject image is incident, and by connecting solder balls 32 disposed on the back surface of the light receiving surface to a wiring substrate 31, it is possible to take out an electric signal to the outside for image recognition.

Furthermore, a thermal expansion adjustment member 51 is provided on the side opposite to the solid-state imaging device 1 mounted on the wiring substrate 31.

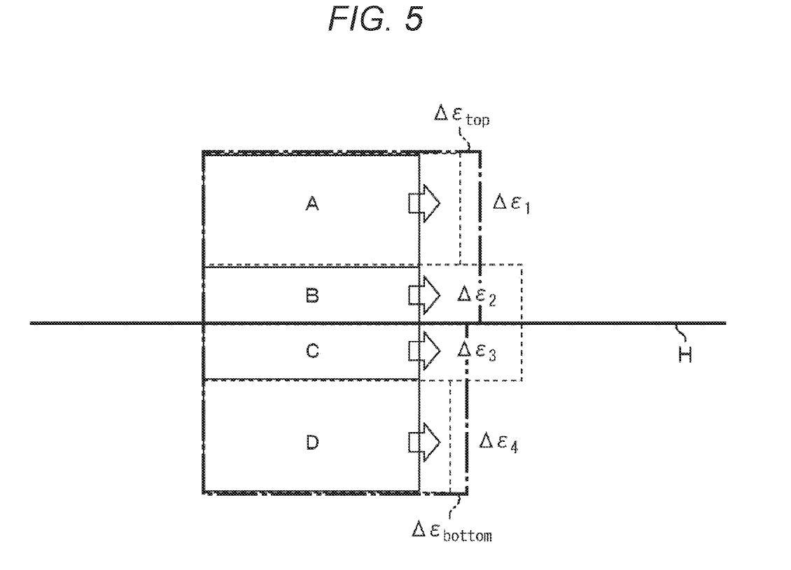

FIG. 5 is a diagram schematically illustrating the structural example of FIG. 4.

A member A has a substance obtained by combining the solid-state imaging device 1 and the solder balls 32, and a member B and a member C represent the wiring substrate 31 in a dividing manner, and a member D corresponds to the thermal expansion adjustment member 51.

The thermal expansion adjustment member 51 is adjusted such that the physical property value and the shape of the thermal expansion adjustment member 51 satisfy the following expressions (1) to (3) so that a neutral plane H with respect to rigidity of the entire structure is within this structure.

$$\begin{matrix}[ Expression 4 ] & \\ ( 1 + {α}_{2} Δ T ) ( 1 - {Δɛ}_{2} ) = ( 1 + {α}_{3} Δ T ) ( 1 - {Δɛ}_{3} ) & ( 1 ) \\ [ Expression 5 ] & \\ {Δɛ}_{2} = \frac{( {α}_{1} - {α}_{2} ) Δ T}{( 1 + {α}_{2} Δ T ) + \frac{1 - {v}_{1} {E}_{2} {t}_{2}}{1 - {v}_{2} {E}_{1} {t}_{1}} ( 1 + {α}_{1} Δ T )} & ( 2 ) \\ [ Expression 6 ] & \\ {Δɛ}_{3} = \frac{( {α}_{4} - {α}_{3} ) Δ T}{( 1 + {α}_{3} Δ T ) + \frac{1 - {v}_{4} {E}_{3} {t}_{3}}{1 - {v}_{3} {E}_{4} {t}_{4}} ( 1 + {α}_{4} Δ T )} & ( 3 )\end{matrix}$$

Here, regarding respective parameters, Δ_{ϵ} represents strain of a member, E represents a Young's modulus, ν represents a Poisson's ratio, α represents a linear expansion coefficient, t represents a thickness, and ΔT represents a temperature change. Regarding suffixes, the member A corresponds to 1, the member B corresponds to 2, the member C corresponds to 3, and the member D corresponds to 4.

The expressions (1) to (3) described above are derived from the definition of the strain and the force balance equation at the neutral plane H. By satisfying these expressions, rigidity is equal between the upper side and the lower side of the neutral plane. In other words, warping can be reduced even if there is a change in environmental temperature or heat generation by the solid-state imaging device 1 during actual use, due to a difference in thermal expansion coefficient between the solid-state imaging device 1 and the wiring substrate 31.

Note that in the example of FIG. 5, the dimensions and the material property of each member may satisfy a variation of ±5% or less, in other words, may be substantially equal. If the dimensions and the material property are within the range of ±5%, warping can be reduced within a practical range as actual design including variations in member and manufacture.

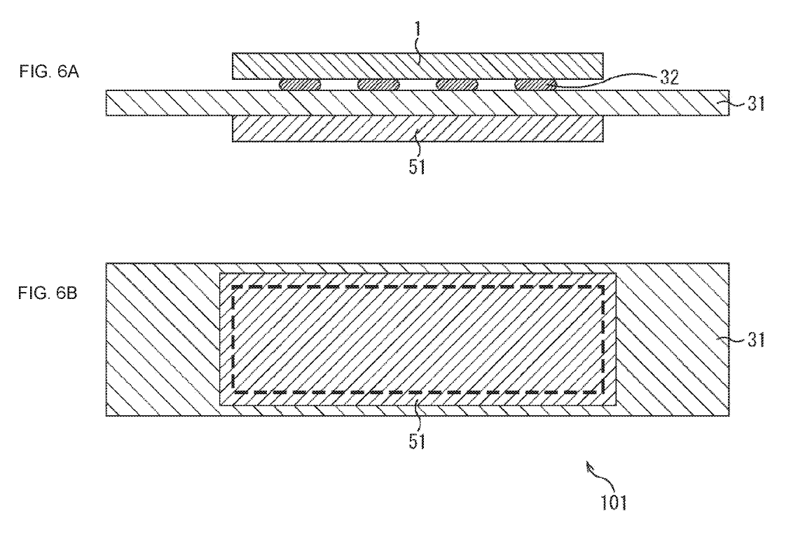

FIG. 6 is a view illustrating another structural example of the mounted substrate to which the present technology is applied. A of FIG. 6 is a view illustrating a cross section of a mounted substrate 101. B of FIG. 6 is a plan view of the mounted substrate 101 of A of FIG. 6 as viewed from below, and the dotted line in the figure indicates the shape of a solid-state imaging device 1 mounted on the back side of a wiring substrate 31.

In other words, in the example of FIG. 6, a thermal expansion adjustment member 51 has the shape equal to the shape of the solid-state imaging device 1. With such a structure, it is possible to increase a warping reduction effect.

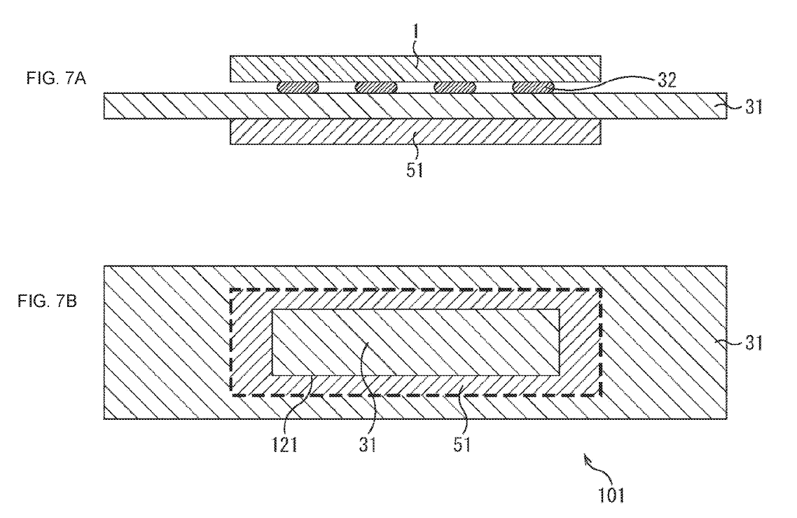

FIG. 7 is a view illustrating another structural example of the mounted substrate to which the present technology is applied. A of FIG. 7 is a view illustrating a cross section of a mounted substrate 101. B of FIG. 7 is a plan view of the mounted substrate 101 of A of FIG. 7 as viewed from below, and the dotted line in the figure indicates the shape of a solid-state imaging device 1 mounted on the back side of a wiring substrate 31.

In other words, in the example of FIG. 7, a thermal expansion adjustment member 51 has an opening 121. With such a structure, the warping reduction effect is slightly weakened; however, it is possible to dispose a device sensitive to external force in the opening 121.

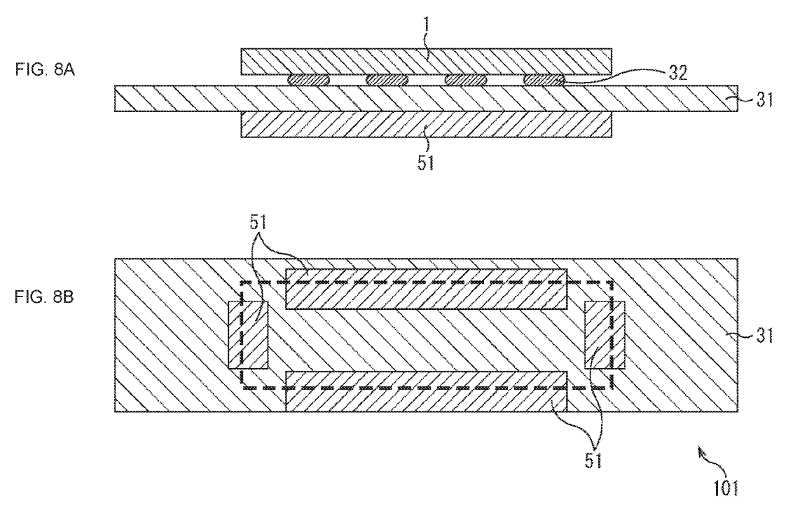

FIG. 8 is a view illustrating another structural example of the mounted substrate to which the present technology is applied. A of FIG. 8 is a view illustrating a cross section of a mounted substrate 101. B of FIG. 8 is a plan view of the mounted substrate 101 of A of FIG. 8 as viewed from below, and the dotted line in the figure indicates the shape of a solid-state imaging device 1 mounted on the back side of a wiring substrate 31.

In other words, in the example of FIG. 8, a thermal expansion adjustment member 51 has a structure divided into a plurality of (four, in the example of FIG. 8) parts. With such a structure, the warping reduction effect is weaker than that of the structure of FIG. 7 having the opening 121; however, similarly to the structure of FIG. 7, it is possible to dispose a device sensitive to external force at a section where the thermal expansion adjustment member 51 is not provided. Moreover, member costs can be reduced.

Furthermore, although not illustrated, in the mounted substrate 101, the thermal expansion adjustment member 51 may be an active element having an function of supporting the solid-state imaging device 1. An active element is, for example, a sensor for camera shake correction, a memory for storing an image signal, a logic circuit for processing an image signal, or the like. Such a configuration enables not only reduction of warping but also addition of a new function to the solid-state imaging device 1.

Moreover, although not illustrated, unlike the description that has been given assuming that the element mounted on the wiring substrate 31 with the solder balls 32 is the solid-state imaging device 1, the solid-state imaging device 1 may be an inertial sensor such as a gyro sensor or an acceleration sensor. Since the present technology can reduce warping, performance improvement can be expected for a device sensitive to external force (such as an inertial sensor).

As described above, in the present technology, the thermal expansion adjustment member is disposed on the side opposite to the solid-state imaging device mounted on the wiring substrate. The linear expansion coefficient and the Young's modulus of the thermal expansion adjustment member are adjusted, so that rigidity is equal or substantially equal between the solid-state imaging device side and the thermal expansion adjustment member side.

With this arrangement, it is possible to reduce warping due to a difference in thermal expansion coefficient between the solid-state imaging device and the wiring substrate even if a change in environmental temperature occurs or heat is generated by the imaging element during actual use.

Furthermore, it is possible to correct warping before the solid-state imaging device is mounted, and warping can be controlled with high accuracy.

Moreover, it is possible to effectively use wiring resources in the wiring substrate without reducing the wiring resources, and wiring design can be facilitated.

Note that the present technology is not limited to the solid-state imaging device, and as described above, can be applied to a semiconductor element such as a device (for example, a gyro sensor or an acceleration sensor) sensitive to external force generated by warping of the substrate.

Furthermore, the configuration in which the present technology is applied to the CMOS solid-state imaging device has been described hereinbefore; however, the present technology may be applied to a solid-state imaging device such as a charge coupled device (CCD) solid-state imaging device.

### 2. Second Embodiment (Usage Examples of Image Sensor)

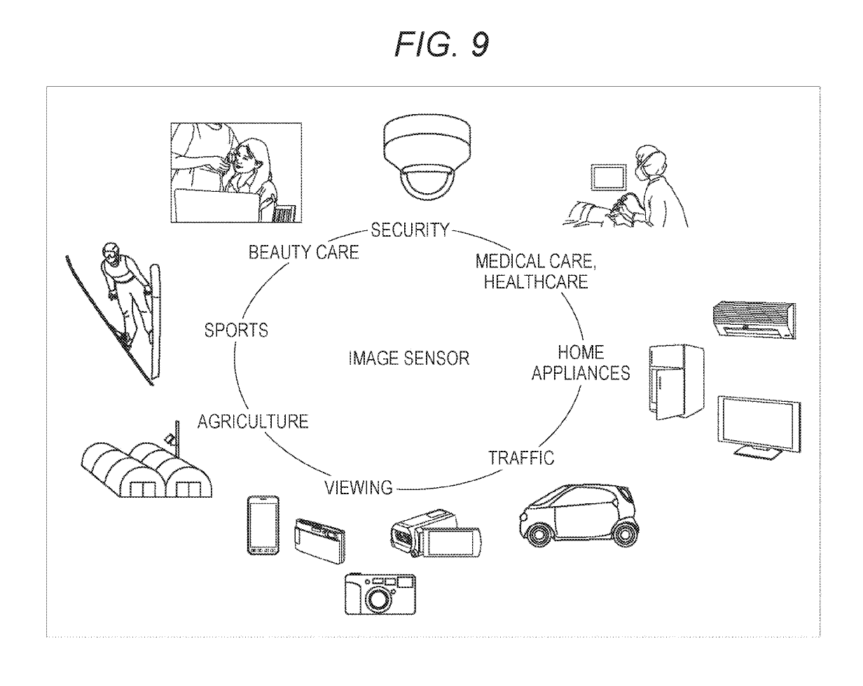

FIG. 9 is a diagram illustrating usage examples of using the solid-state imaging device described above.

The above-described solid-state imaging device (image sensor) can be used, for example, in various cases for sensing light such as visible light, infrared light, ultraviolet light, and X-rays as listed below.

Devices photographing images for viewing, such as a digital camera and a portable device with a camera function

Devices used for traffic such as an in-vehicle sensor for photographing the front, the rear, surroundings, inside, or the like of an automobile for safe driving such as automatic stop, recognition of driver's condition, or the like, a surveillance camera for monitoring traveling vehicles and a road, and a distance measuring sensor for measuring the distance between vehicles and the like

Devices used for home appliances such as a TV, a refrigerator, and an air conditioner, in order to photograph a user's gesture and control the appliance according to the gesture

Devices used for medical care or healthcare, such as an endoscope or a device for performing angiography by receiving infrared light

Devices used for security such as a surveillance camera for prime prevention, and a camera used for person authentication

Devices used for beauty care such as a skin measuring instrument for photographing skin and a microscope for photographing a scalp

Devices used for sports such as an action camera and a wearable camera for sports applications or the like

Devices used for agriculture such as a camera for monitoring the condition of a field and crops

### 3. Third Embodiment (Example of Electronic apparatus)

<Configuration Example of Electronic Apparatus>

Moreover, the present technology is not limited to application to a solid-state imaging device, but can also be applied to an imaging device. Here, the imaging device refers to a camera system such as a digital still camera or a digital video camera, and an electronic apparatus such as a cellphone, having an imaging function. Note that a module-type mode mounted on an electronic apparatus, that is, a camera module may be an imaging device.

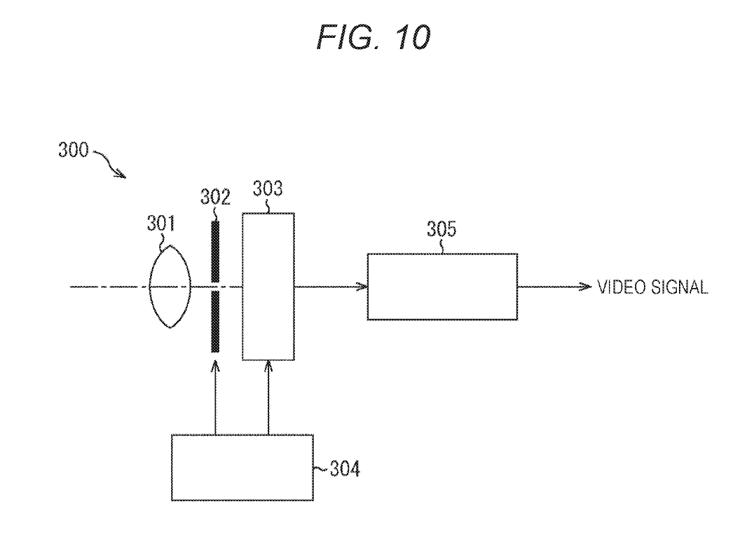

Here, with reference to FIG. 10, a configuration example of the electronic apparatus of the present technology will be described.

An electronic apparatus 300 illustrated in FIG. 10 includes a solid-state imaging device (element chip) 301, an optical lens 302, a shutter device 303, a drive circuit 304, and a signal processing circuit 305. As the solid-state imaging device 301, the above-described solid-state imaging device 1 according to the first embodiment of the present technology is provided. With this arrangement, warping of the solid-state imaging device 301 of the electronic apparatus 300 can be reduced.

The optical lens 302 forms an image of image light (incident light) from a subject on an imaging surface of the solid-state imaging device 301. With this structure, signal charges are accumulated in the solid-state imaging device 301 for a certain period. The shutter device 303 controls a light irradiation period and a light shielding period for the solid-state imaging device 301.

The drive circuit 304 supplies a drive signal for controlling a signal transfer operation of the solid-state imaging device 301 and a shutter operation of the shutter device 303. The solid-state imaging device 301 performs signal transfer according to a drive signal (timing signal) supplied from the drive circuit 304. The signal processing circuit 305 performs various signal processes on the signal output from the solid-state imaging device 301. A video signal subjected to the signal process is stored in a storage medium such as a memory or is output to a monitor.

Note that, herein, the steps describing the above-described series of processes include not only processes that are performed in chronological order according to the described order but also processes performed in parallel or individually, and the processes are not necessarily performed in chronological order.

Furthermore, the embodiments in the present disclosure are not limited to the above-described embodiments, and various modifications are possible within the scope not deviating from the gist of the present disclosure.

Furthermore, the configuration described as one device (or processing unit) hereinbefore may be divided and configured as a plurality of devices (or processing units). In contrast, the configurations described as a plurality of devices (or processing units) hereinbefore may be collectively configured as one device (or processing unit). Furthermore, it goes without saying that a configuration other than those described above may be added to the configuration of each device (or each processing unit). Moreover, if the configuration and operation of the system as a whole are substantially the same, part of the configuration of a certain device (or processing unit) may be included in the configuration of another device (or another processing unit). That is, the present technology is not limited to the above-described embodiments, and various modifications are possible within the scope not deviating from the gist of the present technology.

While preferred embodiments of the present disclosure have been described in detail with reference to the accompanying drawings, the disclosure is not limited to such examples. It is obvious that a person skilled in the art to which the present disclosure pertains can conceive various modifications and corrections within the scope of the technical idea described in the claims, and it is naturally understood that these also belong to the technical scope of the present disclosure.

Note that the present technology can also be configured as follows.

(1) A semiconductor device having a structure including:

a substrate on which a semiconductor element is mounted; and

a thermal expansion adjustment member which is provided on a surface of the substrate, the surface being opposite to a surface on which the semiconductor element is mounted,

in which a substance value and a shape of the thermal expansion adjustment member are adjusted such that a linear expansion coefficient and a Young's modulus are adjusted so as to be substantially equal between a solid-state imaging device side of a neutral plane with respect to entire rigidity of the structure and a thermal expansion adjustment member side of the neutral plane.

(2) The semiconductor device according to (1), in which the substance value and the shape of the thermal expansion adjustment member are adjusted so as to substantially satisfy expressions of

$$\begin{matrix}[ Expression 7 ] & \\ ( 1 + {α}_{2} Δ T ) ( 1 - {Δɛ}_{2} ) = ( 1 + {α}_{3} Δ T ) ( 1 - {Δɛ}_{3} ) , & \\ [ Expression 8 ] & \\ {Δɛ}_{2} = \frac{( {α}_{1} - {α}_{2} ) Δ T}{( 1 + {α}_{2} Δ T ) + \frac{1 - {v}_{1} {E}_{2} {t}_{2}}{1 - {v}_{2} {E}_{1} {t}_{1}} ( 1 + {α}_{1} Δ T )} , and & \\ [ Expression 9 ] & \\ {Δɛ}_{3} = \frac{( {α}_{4} - {α}_{3} ) Δ T}{( 1 + {α}_{3} Δ T ) + \frac{1 - {v}_{4} {E}_{3} {t}_{3}}{1 - {v}_{3} {E}_{4} {t}_{4}} ( 1 + {α}_{4} Δ T )} , & \end{matrix}$$

where, Δ_{ϵ} represents strain of a member, E represents a Young's modulus, ν represents a Poisson's ratio, α represents a linear expansion coefficient, t represents a thickness, and ΔT represents a temperature change.

(3) The semiconductor device according to (2) in which the substance value and the shape of the thermal expansion adjustment member are adjusted so as to substantially satisfy the expressions.

(4) The semiconductor device according to (1) or (2) in which accuracy of each of the substance value and the shape of the thermal expansion adjustment member is adjusted so as to satisfy a variation of ±5% or less.

(5) The semiconductor device according to any one of (1) to (3) in which the thermal expansion adjustment member has a shape substantially equal to a shape of the semiconductor element.

(6) The semiconductor device according to any one of (1) to (5) in which an opening is provided in part of the thermal expansion adjustment member.

(7) The semiconductor device according to any one of (1) to (5) in which the thermal expansion adjustment member is divided into a plurality of parts.

(8) The semiconductor device according to any one of (1) to (7) in which the thermal expansion adjustment member is an active element having a function of supporting the semiconductor element.

(9) The semiconductor device according to any one of (1) to (8) in which the semiconductor element is a solid-state imaging element or an inertial sensor.

(10) A solid-state imaging device having a structure including:

a substrate on which a solid-state imaging element is mounted; and

a thermal expansion adjustment member which is provided on a surface of the substrate, the surface being opposite to a surface on which the solid-state imaging element is mounted,

in which a substance value and a shape of the thermal expansion adjustment member are adjusted such that a linear expansion coefficient and a Young's modulus are adjusted so as to be substantially equal between a solid-state imaging device side of a neutral plane with respect to entire rigidity of the structure and a thermal expansion adjustment member side of the neutral plane.

(11) An electronic apparatus including: an signal processing circuit which processes an output signal output from a solid-state imaging device having a structure including

a substrate on which a solid-state imaging element is mounted, and

a thermal expansion adjustment member which is provided on a surface of the substrate, the surface being opposite to a surface on which the solid-state imaging element is mounted,

in which a substance value and a shape of the thermal expansion adjustment member are adjusted such that a linear expansion coefficient and a Young's modulus are adjusted so as to be substantially equal between a solid-state imaging device side of a neutral plane with respect to entire rigidity of the structure and a thermal expansion adjustment member side of the neutral plane; and

an optical system which causes incident light to be incident on the solid-state imaging device.

### REFERENCE SIGNS LIST

1 Solid-state imaging device
21 Mounted substrate
31 Wiring substrate
32 Solder ball
41 Mounted substrate
51 Thermal expansion adjustment member
52 Wiring substrate
101 Mounted substrate
121 Opening
300 Electronic apparatus
301 Solid-state imaging device
302 Optical lens
303 Shutter device
304 Drive circuit
305 Signal processing circuit

1. A semiconductor device comprising a structure including:
a substrate on which a semiconductor element is mounted; and
a thermal expansion adjustment member which is provided on a surface of the substrate, the surface being opposite to a surface on which the semiconductor element is mounted,
wherein a substance value and a shape of the thermal expansion adjustment member are adjusted such that a linear expansion coefficient and a Young's modulus are adjusted so as to be substantially equal between a solid-state imaging device side of a neutral plane with respect to entire rigidity of the structure and a thermal expansion adjustment member side of the neutral plane.

2. The semiconductor device according to claim 1,
wherein the substance value and the shape of the thermal expansion adjustment member are adjusted so as to substantially satisfy expressions of
$$\begin{matrix}[ Expression 1 ] & \\ ( 1 + {α}_{2} Δ T ) ( 1 - {Δɛ}_{2} ) = ( 1 + {α}_{3} Δ T ) ( 1 - {Δɛ}_{3} ) , & \\ [ Expression 2 ] & \\ {Δɛ}_{2} = \frac{( {α}_{1} - {α}_{2} ) Δ T}{( 1 + {α}_{2} Δ T ) + \frac{1 - {v}_{1} {E}_{2} {t}_{2}}{1 - {v}_{2} {E}_{1} {t}_{1}} ( 1 + {α}_{1} Δ T )} , and & \\ [ Expression 3 ] & \\ {Δɛ}_{3} = \frac{( {α}_{4} - {α}_{3} ) Δ T}{( 1 + {α}_{3} Δ T ) + \frac{1 - {v}_{4} {E}_{3} {t}_{3}}{1 - {v}_{3} {E}_{4} {t}_{4}} ( 1 + {α}_{4} Δ T )} , & \end{matrix}$$
where, Δ_{ϵ} represents strain of a member, E represents a Young's modulus, ν represents a Poisson's ratio, α represents a linear expansion coefficient, t represents a thickness, and ΔT represents a temperature change.

3. The semiconductor device according to claim 2, wherein the substance value and the shape of the thermal expansion adjustment member are adjusted so as to substantially satisfy the expressions.

4. The semiconductor device according to claim 2, wherein accuracy of each the substance value and the shape of the thermal expansion adjustment member is adjusted so as to satisfy a variation of ±5% or less.

5. The semiconductor device according to claim 1, wherein the thermal expansion adjustment member has a shape substantially equal to a shape of the semiconductor element.

6. The semiconductor device according to claim 1, wherein an opening is provided in part of the thermal expansion adjustment member.

7. The semiconductor device according to claim 1, wherein the thermal expansion adjustment member is divided into a plurality of parts.

8. The semiconductor device according to claim 1, wherein the thermal expansion adjustment member is an active element which has a function of supporting the semiconductor element.

9. The semiconductor device according to claim 1, wherein the semiconductor element is a solid-state imaging element or an inertial sensor.

10. A solid-state imaging device comprising a structure including:
a substrate on which a solid-state imaging element is mounted; and
a thermal expansion adjustment member which is provided on a surface of the substrate, the surface being opposite to a surface on which the solid-state imaging element is mounted,
wherein a substance value and a shape of the thermal expansion adjustment member are adjusted such that a linear expansion coefficient and a Young's modulus are adjusted so as to be substantially equal between a solid-state imaging device side of a neutral plane with respect to entire rigidity of the structure and a thermal expansion adjustment member side of the neutral plane.

11. An electronic apparatus comprising:
an signal processing circuit which processes an output signal output from a solid-state imaging device having a structure including
a substrate on which a solid-state imaging element is mounted, and
a thermal expansion adjustment member which is provided on a surface of the substrate, the surface being opposite to a surface on which the solid-state imaging element is mounted,
wherein a substance value and a shape of the thermal expansion adjustment member are adjusted such that a linear expansion coefficient and a Young's modulus are adjusted so as to be substantially equal between a solid-state imaging device side of a neutral plane with respect to entire rigidity of the structure and a thermal expansion adjustment member side of the neutral plane; and
an optical system which causes incident light to be incident on the solid-state imaging device.
